(19) United States
(12) Patent Application Publication
(10) Pub. No.: US 2009/0255717 A1
(43) Pub. Date: Oct. 15, 2009

(54) Suspension Board with Circuit and Production Method Thereof

(75) Inventors: Aya Mizushima, Osaka (JP); Toshiki Naito, Osaka (JP)

Correspondence Address: AKERMAN SENTERFITT, 8100 BOONE BOULEVARD, SUITE 700, VIENNA, VA, 22182-2683, US

(73) Assignee: NITTO DENKO CORPORATION, Osaka (JP)

(21) Appl. No.: 12/385,626

(22) Filed: Apr. 14, 2009

Related U.S. Application Data
(60) Provisional application No. 61/071,406, filed on Apr. 28, 2008.

(30) Foreign Application Priority Data
Apr. 14, 2008 (JP) 2008-105034

(51) Int. Cl. H05K 1/03; C25D 5/02

(52) U.S. Cl. 174/255; 205/125

(57) ABSTRACT

A suspension board with circuit includes an insulating layer formed with a first opening, a conductive layer formed on the insulating layer so as to fill the first opening, a metal thin film formed so as to cover a surface of the conductive layer exposed from the first opening, and be interposed between the conductive layer and the insulating layer, and a metal supporting layer formed with a second opening surrounding the first opening so as to underlie the insulating layer. The metal supporting layer includes a covering portion provided in the second opening so as to cover the first opening.

### CROSS-REFERENCE TO RELATED APPLICATION

This application claims the benefit of U.S. Provisional Application No. 61/071,406, filed on Apr. 28, 2008, and claims priority from Japanese Patent Application No. 2008-105034, filed on Apr. 14, 2008, the contents of which are herein incorporated by reference in their entirety.

### BACKGROUND OF THE INVENTION

1. Field of the Invention

The present invention relates to a suspension board with circuit, and a production method thereof.

2. Description of the Related Art

Conventionally, a suspension board with circuit has been known which includes a metal supporting layer, an insulating layer formed on the metal supporting layer, a conductive layer formed on the insulating layer, and a metal thin film interposed between the conductive layer and the insulating layer.

In the production of such a suspension board with circuit, after a second opening is formed in an insulating layer, and a conductive layer is formed so as to fill the second opening, a pad portion is formed using a metal supporting layer as a lead portion for electrolytic plating. To prevent a short circuit between the metal supporting layer and the conductive layer, it is proposed to subsequently bore a first opening larger than the second opening in the portion of the metal supporting layer opposing the second opening (see, e.g., Japanese Unexamined Patent No. 2005-100488).

In the suspension board with circuit described in Japanese Unexamined Patent No. 2005-100488, the conductive layer is covered with a metal thin film without being exposed directly to the outside from the second opening. This prevents corrosion of the conductive layer.

### SUMMARY OF THE INVENTION

However, in recent years, a higher quality has been required of the suspension board with circuit. In the suspension board with circuit described in Japanese Unexamined Patent No. 2005-100488, the prevention of corrosion of the conductive layer may not be sufficient.

That is, during the production process of the suspension board with circuit, when a stress resulting from ultrasonic cleaning or the like is applied on the end edge of the second opening, the metal thin film is prone to interfacial delamination from the insulating layer. In that case, in the subsequent process step, a chemical solution enters the interface between the metal thin film and the insulating layer, and remains in the interface. As a result, the conductive layer may be discolored (corroded).

When there is a defect such as a pinhole in the metal thin film exposed from the second opening, the conductive layer exposed from the pinhole may also be discolored (corroded).

It is therefore an object of the present invention to provide a suspension board with circuit in which the corrosion of a conductive layer is effectively prevented, and a production method thereof.

To attain the object, a suspension board with circuit of the present invention includes an insulating layer formed with a first opening, a conductive layer formed on the insulating layer so as to fill the first opening, a metal thin film formed so as to cover a surface of the conductive layer exposed from the first opening, and be interposed between the conductive layer and the insulating layer, and a metal supporting layer formed with a second opening surrounding the first opening so as to underlie the insulating layer, wherein the metal supporting layer includes a covering portion provided in the second opening so as to cover the first opening.

A production method of a suspension board with circuit of the present invention includes forming, on a metal supporting layer, an insulating layer formed with a first opening, forming a metal thin film on a surface of the insulating layer and on a surface of the metal supporting layer exposed from the first opening, forming a conductive layer by plating on a surface of the metal thin film formed on the insulating layer and in the first opening so as to provide electrical conduction between the conductive layer and the metal supporting layer via the metal thin film, forming a terminal portion on the conductive layer by electrolytic plating using the metal supporting layer as a lead for the electrolytic plating, and forming, in the metal supporting layer, a second opening surrounding the first opening so as to leave a covering portion covering the first opening.

In the suspension board with circuit of the present invention, the first opening is covered with the covering portion. Accordingly, in a cleaning step or the like, it is possible to prevent entrance of a chemical solution into the first opening.

In particular, even when a stress is applied on the insulating layer and on the conductive layer filling the first opening of the insulating layer during the production process, and the metal thin film in the first opening is interfacially delaminated from the insulating layer, the covering portion covering the first opening can prevent entrance of a chemical solution into the interface between the metal thin film and the insulating layer in the first opening. This allows effective prevention of corrosion of the conductive layer.

In addition, even when there is a defect in the metal thin film exposed from the first opening, the covering portion covering the first opening can effectively prevent corrosion of the conductive layer.

Moreover, since the first opening portion filled with the conductive layer is surrounded by the second opening, a short circuit between the conductive layer and the metal supporting layer can be prevented.

As a result, it is possible to ensure high reliability, while preventing corrosion of the conductive layer.

In accordance with the production method of the suspension board with circuit of the present invention, the second opening is bored so as to leave the covering portion covering the first opening. Accordingly, in a cleaning step or the like, it is possible to prevent entrance of a chemical solution into the first opening.

In particular, even when a stress is applied on the insulating layer and on the conductive layer filling the first opening of the insulating layer during the production process, and the metal thin film in the first opening is interfacially delaminated from the insulating layer, the covering portion covering the first opening can prevent entrance of the chemical solution into the interface between the metal thin film and the insulating layer in the first opening. This allows effective prevention of corrosion of the conductive layer.

In addition, even when there is a defect in the metal thin film exposed from the first opening, the covering portion covering the first opening can effectively prevent corrosion of the conductive layer.

Moreover, in the production method, the metal supporting layer is opened to be provided with the second opening surrounding the first opening. This can prevent a short circuit between the conductive layer and the metal supporting layer.

As a result, it is possible to provide a suspension board with circuit in which the corrosion of the conductive layer is prevented, while ensuring high reliability.

### BRIEF DESCRIPTION OF THE DRAWINGS

FIG. 1 is a plan view showing an embodiment of a suspension board with circuit of the present invention;

FIG. 2 is a process view for illustrating an embodiment of a production method of the suspension board with circuit of the present invention,

(a) showing the step of forming, on a supporting board, an insulating base layer formed with a first opening,

(b) showing the step of forming a metal thin film on a surface of the insulating base layer and on the surface of the supporting board exposed from the first opening,

(c) showing the step of forming a conductive layer by plating,

(d) showing the step of removing the metal thin film exposed from the conductive layer, and

(e) showing the step of forming a metal coating;

FIG. 3 is a process view for illustrating, subsequently to FIG. 2, the embodiment of the production method of the suspension board with circuit of the present invention,

(f) showing the step of forming an insulating cover layer formed with a pad opening,

(g) showing the step of removing the metal coating exposed from the pad opening,

(h) showing the step of forming a pad by electrolytic plating on the surface of the conductive layer exposed from the pad opening, and

(i) showing the step of opening the supporting board so as to provide a second opening, and leave a covering portion; and

FIG. 4 is an enlarged bottom view of the covering portion of the suspension board with circuit shown in FIG. 1.

### DETAILED DESCRIPTION OF THE INVENTION

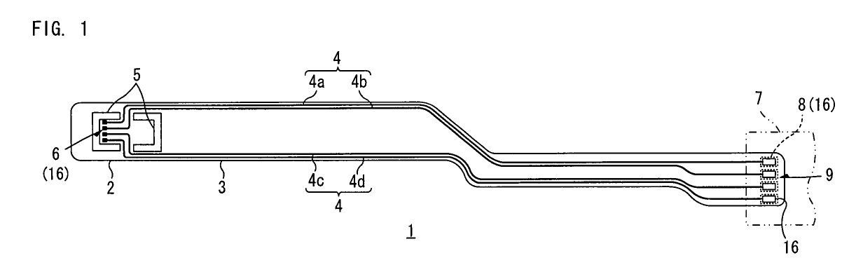

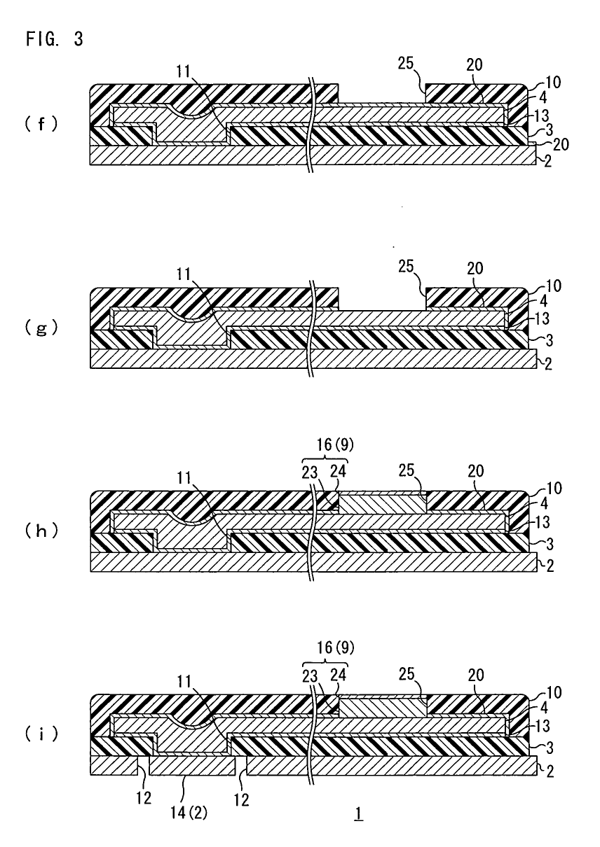

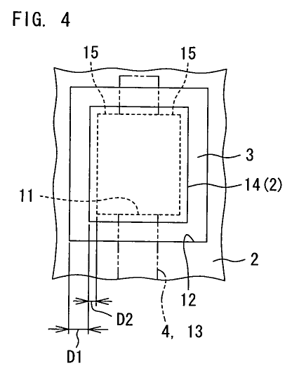

FIG. 1 is a plan view showing an embodiment of a suspension board with circuit of the present invention. FIG. 3(i) is an enlarged plan view of a principal portion of the suspension board with circuit shown in FIG. 1. FIG. 4 is an enlarged bottom view of a covering portion (described later) of the suspension board with circuit shown in FIG. 1. FIG. 3(i) shows a part of a cross section of the suspension board with circuit along the longitudinal direction thereof which includes the portion of the suspension board with circuit where external connection terminal portions (described later) are formed.

In FIG. 1, a suspension board with circuit 1, on which a magnetic head (not shown) of a hard disk drive is mounted, supports the magnetic head, while holding a minute gap between the magnetic head and a magnetic disk, against an air flow when the magnetic head and the magnetic disk travel relatively to each other. In the suspension board with circuit 1, a conductive layer 4 for connecting the magnetic head and a read/write board as an external circuit is integrally formed as a wired circuit pattern.

As shown in FIGS. 1 and 3(i), the suspension board with circuit 1 includes a supporting board 2 as a metal supporting layer extending in a longitudinal direction, an insulating base layer 3 as an insulating layer made of an insulating material, and formed on the supporting board 2, and a conductive layer 4 formed as the wired circuit pattern on the insulating base layer 3. The suspension board with circuit 1 also includes a metal thin film 13 interposed between the conductive layer 4 and the insulating base layer 3. The wired circuit pattern is formed as a plurality of wires 4a, 4b, 4c, and 4d which are arranged in parallel in mutually spaced-apart relation.

In a front end portion (one end portion in the longitudinal direction) of the supporting board 2, a gimbal 5 for mounting the magnetic head is formed by cutting out the supporting board 2. On the front end portion of the supporting board 2, magnetic-head-side connection terminal portions 6 as terminal portions for connecting the magnetic head and the individual wires 4a, 4b, 4c, and 4d are formed.

On a rear end portion of the supporting board 2, external connection terminal portions 9 as terminal portions for connecting terminal portions 8 (broken lines) of a read/write board 7 (imaginary line) and the individual wires 4a, 4b, 4c, and 4d are formed. The external connection terminal portions 9 are formed as individual pads 16 each made of a gold plating layer 24 and a nickel plating layer 23 on the conductive layer 4 exposed from pad openings 25 each having a generally rectangular shape. The pad openings 25 are bored in an insulating cover layer 10, described later, correspondingly to the individual wires 4a, 4b, 4c, and 4d at the respective rear end portions (the other end portion in the longitudinal direction) of the wires 4a, 4b, 4c, and 4d.

In FIG. 1, the conductive layer 4 is actually covered with the insulating cover layer 10 made of an insulating material, though not shown.

In the suspension board with circuit 1, first openings 11 are formed in the insulating base layer 3 and filled with the conductive layer 4, while second openings 12 are formed in the supporting board 2.

As shown in FIG. 3(i), the first openings 11 are each formed in the insulating base layer 3 to extend therethrough in a thickness direction. When viewed in bottom (plan) view, each of the first openings 11 is provided at a position different from the corresponding pad 16. Specifically, the first opening 11 is disposed to be spaced apart from the pad 16 in the longitudinal direction. As indicated by the broken line in FIG. 4, the first opening 11 is formed in a generally rectangular shape when viewed in bottom view. The size of the first opening 11 is such that a length of a side thereof is in a range of, e.g., 30 to 2000 μm, or preferably 60 to 1000 μm.

The conductive layer 4 is formed to correspond to the first opening 11. The conductive layer 4 is formed with protruding portions 15 which protrude from each of the wires 4a, 4b, 4c, and 4d in a widthwise direction at portions where the conductive layer 4 is filled in the first opening 11. As shown in FIG. 3(i), the surfaces of the conductive layer 4 which are exposed from the first opening 11 are covered with the metal thin film 13.

As shown in FIGS. 3(i) and 4, each of the second openings 12 is disposed in the supporting board 2 to oppose the corresponding first opening 11 in the thickness direction, and formed so as to extend through the supporting board 2 in the thickness direction. More specifically, the second opening 12 is formed in a generally rectangular shape larger than and surrounding the first opening 11 (protruding portions 15) when projected in the thickness direction and viewed in bottom view.

The size of the second opening 12 is such that a length of a side thereof is in a range of, e.g., 50 to 2000 μm, or preferably 80 to 1000 μm.

Further, the supporting board 2 includes covering portions 14.

Each of the covering portions 14 is provided in the corresponding second opening 12 to cover the first opening 11.

That is, the covering portion 14 is disposed to be spaced apart from the inner side surface of the second opening 12. Specifically, the covering portion 14 is disposed such that the outer side surface thereof is located interior (longitudinally and widthwise interior) to the inner side surface of the second opening 12, and exterior (longitudinally and widthwise exterior) to the inner side surface of the first opening 11 when viewed in bottom view (when projected in the thickness direction). That is, the outer side surface of the covering portion 14 is located between the inner side surface of the second opening 12 and the inner side surface of the first opening when viewed in bottom view (when projected in the thickness direction).

The upper surface of the covering portion 14 is in contact with the lower surface of the conductive layer 4 (the metal thin film 13 formed on the lower surface of the conductive layer 4 exposed from the first opening 11) exposed from the first opening 11 and with the lower surface of the insulating base layer 3 around the peripheral end of the first opening 11. As a result, the covering portion 14 is in conduction with the conductive layer 4 via the metal thin film 13, while the electrical conduction thereof with the supporting board 2 around the outer periphery of the second opening 12 is interrupted.

The position and size of the covering portion 14 are set appropriately in accordance with the respective sizes of the first opening 11 and the second opening 12. Specifically, the distance D1 between the outer side surface of the covering portion 14 and the inner side surface of the second opening 12 is in a range of, e.g., 30 to 300 μm, or preferably 50 to 100 μm, and the distance D2 between the outer side surface of the covering portion 14 and the inner side surface of the first opening 11 is in a range of, e.g., 5 to 100 μm, or preferably 10 to 50 μm.

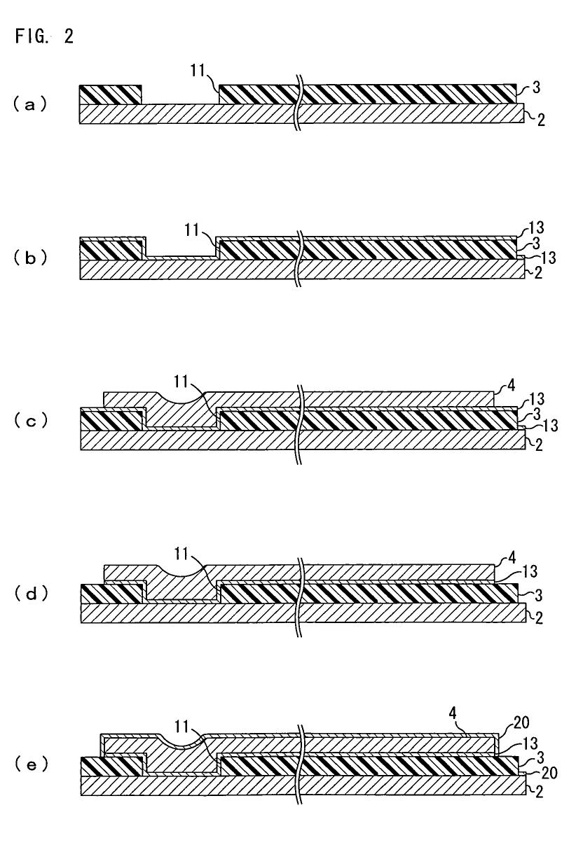

Next, an embodiment of a production method of the suspension board with circuit of the present invention is described with reference to FIGS. 2 and 3. FIGS. 2 and 3 show a part of a cross section of the suspension board with circuit 1 along the longitudinal direction thereof which includes the portion of the suspension board with circuit 1 where the external connection terminal portions 9 are formed.

In the method, as shown in FIG. 2(a), the supporting board 2 is prepared, and the insulating base layer 3 to be formed with the first opening 11 is formed in a predetermined pattern on the supporting board 2.

As the supporting board 2, a metal foil or a metal thin plate, e.g., is used. Examples of such a metal used for the metal foil or the metal thin plate include stainless steel, and a 42-alloy. Preferably, stainless steel is used. The thickness of the supporting board 2 is in a range of, e.g., 10 to 60 μm, or preferably 15 to 30 μm. The width of the supporting board 2 is in a range of, e.g., 50 to 500 mm, or preferably 125 to 300 mm.

An insulating material for forming the insulating base layer 3 is not particularly limited. Any insulating material can be used as long as it can be used as an insulating material for a suspension board with circuit. Examples of such an insulating material that can be listed include a polyimide resin, an acrylic resin, a polyether nitrile resin, a polyether sulfone resin, a polyethylene terephthalate resin, a polyethylene naphthalate resin, and a polyvinyl chloride resin. Among them, a photosensitive synthetic resin is preferably used, or more preferably, a photosensitive polyimide resin is used.

In the case where the insulating base layer 3 is formed of a polyimide resin, and the supporting board 2 is formed of stainless steel, it is possible to provide contact and excellent adhesion between the insulating base layer 3 around the peripheral end of the first opening 11 and the covering portion 14. As a result, the covering portion 14 can prevent entrance of a chemical solution into the first opening 11.

To form the insulating base layer 3 in a predetermined pattern including the first openings 11 on the supporting board 2 using a photosensitive polyimide resin, e.g., a varnish of the photosensitive polyimide resin is coated on a surface of the supporting board 2, subjected to photoprocessing, and then cured. In the case where a photosensitive synthetic resin is not used, e.g., a synthetic resin is coated with a predetermined pattern on the supporting board 2, or sticked as a dry film in the shape of the predetermined pattern to the supporting board 2.

Next, as shown in FIG. 2(b), the metal thin film 13 is formed on the surface of the insulating base layer 3 and on the surface of the supporting board 2 exposed from the first opening 11.

For the formation of the metal thin film 13, a vacuum vapor deposition method, especially a sputter vapor deposition method is preferably used. As the metal forming the metal thin film 13, chromium, copper, or the like is preferably used. More specifically, e.g., a chromium thin film and a copper thin film are successively formed by the sputter vapor deposition method on the surface (the upper surface of the insulating base layer 3 and the inner side surfaces of the first opening 11 in the insulating base layer 3) of the insulating base layer 3 and on the surface of the supporting board 2 exposed from the first opening 11. The thickness of the chromium thin film is in a range of, e.g., 100 to 600 Å, and the thickness of the copper thin film is in a range of, e.g., 500 to 2000 Å.

Next, as shown in FIG. 2(c), the conductive layer 4 is formed by plating on the surface of the metal thin film 13 formed on the insulating base layer 3 and in the first opening 11.

The conductive layer 4 is made of a conductive material which is not particularly limited. Any conductive material can be used as long as it can be used as a conductive material for a suspension board with circuit. Examples of such a conductive material that can be used include copper, nickel, gold, a solder, or an alloy thereof. Preferably, copper is used.

To form the conductive layer 4 by plating, a plating resist in a pattern reverse to the wired circuit pattern is formed first on the metal thin film 13, and then the conductive layer 4 in the same pattern as the wired circuit pattern is formed by plating on the portion of the insulating base layer 3 where the plating resist is not formed. Plating may be either electrolytic plating or electroless plating. Preferably, electrolytic plating is used, or more preferably, electrolytic copper plating is used.

The conductive layer 4 thus formed fills the first opening 11 where it is in electrical conduction with the supporting board 2 via the metal thin film 13. As shown in FIG. 1, the conductive layer 4 is formed, e.g., in a pattern including the plurality of wires 4a, 4b, 4c, and 4d which are arranged in parallel, and spaced apart from each other at predetermined spacings.

The thickness of the conductive layer 4 is in a range of, e.g., 2 to 15 μm, or preferably 5 to 10 μm. The width of each of the wires 4a, 4b, 4c, and 4d is in a range of, e.g., 10 to 500 μm, or preferably 30 to 200 μm. The spacing between the individual wires 4a, 4b, 4c, and 4d is in a range of, e.g., 10 to 200 μm, or preferably 30 to 100 μm.

Thereafter, the plating resist is removed by, e.g., known etching such as chemical etching (wet etching), or stripping.

Next, as shown in FIG. 2(d), the metal thin film 13 (i.e., the portion of the metal thin film 13 where the plating resist is formed) exposed from the conductive layer 4 is similarly removed by known etching such as chemical etching (wet etching).

Thereafter, as shown in FIG. 2(e), the metal coating 20 is formed on the surface of the conductive layer 4 and on the surface of the supporting board 20. Preferably, the metal coating 20 is formed as a hard nickel coating by electroless nickel plating. The thickness of the metal coating 20 is sufficient as long as it prevents the surface of the conductive layer 4 from being exposed, and is in a range of, e.g., 0.05 to 0.1 μm.

Next, as shown in FIG. 3(f), the insulating cover layer 10 for covering the conductive layer 4 is formed in a predetermined pattern. As an insulating material for forming the insulating cover layer 10, the same insulating material as used to form the insulating base layer 3 is used. Preferably a photosensitive polyimide resin is used.

To form the insulating cover layer 10, the same method as used to form the insulating base layer 3 is used. In the insulating cover layer 10 thus formed, the pad opening 25 is formed, and the insulating cover layer 10 exposes the conductive layer 4 (the metal coating 20 formed on the surface of the conductive layer 4) from the pad opening 25. The thickness of the insulating cover layer 10 is in a range of, e.g., 1 to 30 μm, or preferably 2 to 5 μm.

Next, as shown in FIG. 3(g), the metal coating 20 exposed from the pad opening 25 is removed by, e.g., stripping or the like. At the same time, the metal coating 20 formed on the supporting board 2 is also removed.

Next, as shown in FIG. 3(h), the pad 16 is formed by electrolytic plating on (the upper surface of) the conductive layer 4 exposed from the pad opening 25. The metal used for electrolytic plating is not particularly limited. Any metal can be used as long as it can form the terminal portions of a suspension board with circuit. Examples of the metal that can be used include copper, nickel, chromium, and gold.

To form the pad 16 by electrolytic plating, the supporting board 2 and the insulating cover layer 10 are covered first with a plating resist, except for the portions thereof where the pad 16 is to be formed. Then, in this step, since the conductive layer 4 is in electrical conduction with the supporting board 2 via the metal thin film 13 in the first opening 11, electrolytic plating is performed using the supporting board 2 as a lead for electrolytic plating.

The pad 16 may also be formed of multiple layers. For example, as shown in FIG. 3(h), electrolytic nickel plating and electrolytic gold plating are successively performed to successively form the nickel plating layer 23 and the gold plating layer 24 thereon. The respective thicknesses of the nickel plating layer 23 and the gold plating layer 24 are each in a range of, e.g., 1 to 5 μm.

Thereafter, as shown in FIG. 3(i), the supporting board 2 is opened.

To open the supporting board 2, e.g., etching such as dry etching or wet etching (chemical etching), drilling, laser processing, or the like is used. Preferably, etching is used.

That is to say, in the supporting board 2, the second opening 12 surrounding the first opening 11 is bored so as to leave the covering portion 14 covering the first opening 11.

At the same time as the supporting board 2 is opened, the gimbal 5 and an outer shape of the suspension board with circuit 1 are formed by trimming, as shown in FIG. 1, to provide the suspension board with circuit 1.

Although a formation method of the magnetic-head-side connection terminal portions 6 has not been described above, the magnetic-head-side connection terminal portions 6 are also formed in the same manner as the external connection terminal portions 9 are formed.

In the suspension board with circuit 1 obtained by this method, the first opening 11 is covered with the covering portion 14. Accordingly, in a cleaning step after the production of the suspension board with circuit 1 or the like, it is possible to prevent entrance of a chemical solution into the first opening 11.

In particular, even when a stress is applied on the insulating base layer 3 and on the conductive layer 4 filling the first opening 11 of the insulating base layer 3 during the production process of the suspension board with circuit 1, and the metal thin film 13 in the first opening 11 is interfacially delaminated from the insulating base layer 3, the covering portion 14 covering the first opening 11 can prevent entrance of a chemical solution into the interface between the metal thin film 13 and the insulating base layer 3 in the first opening 11. This allows effective prevention of corrosion of the conductive layer 4.

Even when there is a defect in the metal thin film 13 exposed from the first opening 11, the covering portion 14 covering the first opening 11 can effectively prevent corrosion of the conductive layer 4.

Moreover, since the first opening 11 filled with the conductive layer 4 is surrounded by the second opening 12, a short circuit between the conductive layer 4 and the supporting board 2 can be prevented.

As a result, it is possible to ensure high reliability, while preventing corrosion of the conductive layer 4.

In the suspension board with circuit 1 obtained by this method, the supporting board 2 is in electrical conduction with the conductive layer 4 via the metal thin film 13 in the step of forming the pad 16 by electrolytic plating prior to the opening of the first opening 11, as shown in FIG. 3(h). Therefore, in this step, the supporting board 2 can be used as a lead for electrolytic plating for forming the pad 16.

In the description given above, each of the first opening 11, the second opening 12, and the covering portion 14 is formed to have a generally rectangular shape when viewed in bottom view, but the shape thereof is not particularly limited. Each of the first opening 11, the second opening 12, and the covering portion 14 can be formed into an appropriate shape depending on the purpose and application thereof. For example, each of the first opening 11, the second opening 12, and the covering portion 14 can be formed into a generally circular shape, a generally polygonal shape (except for a rectangular shape), or the like when viewed in bottom view, though not shown.

In the description given above, the conductive layer 4 in the first opening 11 is formed with the protruding portions 15. However, when the width of the first opening 11 is the same as that of each the wires 4a, 4b, 4c, and 4d, it is also possible to, e.g., form the conductive layer 4 into a linear shape without forming the protruding portions 15, though not shown.

In the description given above, the metal coating 20 is formed on the surface of the conductive layer 4. However, it is also possible to, e.g., form the insulating cover layer 10 directly on the surface of the conductive layer 4 without forming the metal coating 20, though not shown.

### EXAMPLES

Hereinbelow, the present invention is described more specifically by showing the example and the comparative example. However, the present invention is by no means limited to the example and the comparative examples.

(Production of Suspension Board with Circuit)

### Example 1

A supporting board made of stainless steel having a thickness of 25 μm was prepared. Then, a varnish of a polyamic acid resin was coated on the surface of the supporting board, and heated at 130° C. to form a coating of the polyamic acid resin. Thereafter, the coating was exposed to light via a photomask, and the exposed portion was dried by heating at 180° C., and then developed using an alkaline developer to form the coating in a pattern.

Then, the coating was cured (imidized) by heating at 350° C. to form an insulating base layer made of a polyimide resin having a thickness of 15 μm in a pattern including a first opening (see FIG. 2(a)). The first opening was in a rectangular shape with a side having a length of 60 μm when viewed in plan view.

Then, a chromium thin film having a thickness of 300 Å and a copper thin film having a thickness of 700 Å were successively formed by a sputter vapor deposition method on the surface of the insulating base layer and on the surface of the supporting board exposed from the first opening (see FIG. 2(b)).

Thereafter, a plating resist in a pattern reverse to a wired circuit pattern was formed using a dry film resist. Then, by electrolytic copper plating, a conductive layer in the same pattern as the wired circuit pattern was formed on the portion of the insulating base layer where the plating resist was not formed (see FIG. 2(c)).

Thereafter, the plating resist was removed by chemical etching, and then the chromium thin film and the copper thin film at the portion where the plating resist was formed were removed by chemical etching (see FIG. 2(d)).

In this step, the first opening was filled with the conductive layer, and the conductive layer was in electrical conduction with the supporting board via the metal thin film.

The conductive layer was formed to have a thickness of 20 μm in the wired circuit pattern including four wires each having a width of 20 μm which were arranged in parallel, and spaced apart from each other at spacings of 30 μm.

Then, a metal coating made of hard nickel having a thickness of 0.1 μm was formed by electroless nickel plating on the surface of the conductive layer and on the surface of the supporting board (see FIG. 2(e)).

Thereafter, a varnish of a polyamic acid resin was coated on the metal coating and on the insulating base layer, and then heated at 130° C. to form a coating of the polyamic acid resin. Thereafter, the coating was exposed to light via a photomask, and the exposed portion was dried by heating at 180° C., and then developed using an alkaline developer to form the coating into a pattern where the conductive layer was covered, and pad openings were formed.

Then, the coating was cured (imidized) by heating at 350° C. to form an insulating cover layer made of a polyimide resin having a thickness of 3 μm on the conductive layer (see FIG. 3f).

Thereafter, the metal coating formed on the surface of the supporting board and in the pad openings of the conductive layer for magnetic-head-side connection terminals and external connection terminals was stripped (see FIG. 3(g)).

Then, pads were formed by electrolytic plating on the upper surface of the conductive layer exposed from the pad openings. To form the pads, electrolytic nickel plating and electrolytic gold plating were successively performed using the supporting board as a lead for electrolytic plating. The thickness of a nickel plating layer in each of the pads was 2 μm, and the thickness of a gold plating layer in each of the pads was 1 μm.

Thereafter, the supporting board was opened. In the opening of the supporting board, chemical etching was performed with respect to the metal supporting layer so as to leave a covering portion covering the first opening, and provide a second opening surrounding the first opening (see FIG. 3(i). At the same time, trimming was performed to form a gimbal, and an outer shape of a suspension board with circuit (see FIG. 1).

The first opening had a rectangular shape when viewed in bottom view, and a length of a side thereof was 140 μm. The distance (D1) between the outer side surface of the covering portion and the inner side surface of the second opening was 70 μm, and the distance (D2) between the outer side surface of the covering portion and the inner side surface of the first opening was 20 μm.

### COMPARATIVE EXAMPLE 1

A suspension board with circuit was obtained by providing the second opening in the same manner as in EXAMPLE 1, except that the covering portion was not left.

That is, the supporting board was opened so as to expose the first opening in the second opening.

(Evaluation)

An ultrasonic cleaning test was conducted on each of the suspension boards with circuits according to EXAMPLE 1 and COMPARATIVE EXAMPLE 1. Specifically, the suspension boards with circuits were each subjected to a 30-minute ultrasonic treatment at 132 KHz in pure water using an ultrasonic cleaner. Then, the suspension boards with circuits were each dipped in an alkaline etchant for 30 minutes, collected, and dried. Thereafter, the conductive layers were each visually observed.

As a result, in the suspension board with circuit according to EXAMPLE 1, coloration (corrosion) of the conductive layer could not be observed.

By contrast, in the suspension board with circuit according to COMPARATIVE EXAMPLE 1, coloration (corrosion) of the conductive layer was observed.

While the illustrative embodiments of the present invention are provided in the above description, such is for illustrative purpose only and it is not to be construed limitative. Modification and variation of the present invention which will be obvious to those skilled in the art is to be covered by the following claims.

What is claimed is:

1. A suspension board with circuit comprising:
an insulating layer formed with a first opening;
a conductive layer formed on the insulating layer so as to fill the first opening;
a metal thin film formed so as to cover a surface of the conductive layer exposed from the first opening, and be interposed between the conductive layer and the insulating layer; and
a metal supporting layer formed with a second opening surrounding the first opening so as to underlie the insulating layer, wherein
the metal supporting layer comprises a covering portion provided in the second opening so as to cover the first opening.

2. A production method of a suspension board with circuit, the production method comprising:
forming, on a metal supporting layer, an insulating layer formed with a first opening;
forming a metal thin film on a surface of the insulating layer and on a surface of the metal supporting layer exposed from the first opening;
forming a conductive layer by plating on a surface of the metal thin film formed on the insulating layer and in the first opening so as to provide electrical conduction between the conductive layer and the metal supporting layer via the metal thin film;
forming a terminal portion on the conductive layer by electrolytic plating using the metal supporting layer as a lead for the electrolytic plating; and
forming, in the metal supporting layer, a second opening surrounding the first opening so as to leave a covering portion covering the first opening.
